(19) United States
(12) Patent Application Publication
(10) Pub. No.: US 2026/0291446 A1
(43) Pub. Date: Sep. 24, 2026

(54) APPARATUS AND METHODS FOR DELAY CALIBRATION OF LOAD MODULATED POWER AMPLIFIERS AND ENVELOPE TRACKERS

(71) Applicant: Skyworks Solutions, Inc., Irvine, CA (US)

(72) Inventors: Serge Francois Drogi, Flagstaff, AZ (US); Harish Shamanna Muthali, San Jose, CA (US); David Steven Ripley, Sanibel, FL (US)

(21) Appl. No.: 19/569,298

(22) Filed: Mar. 17, 2026

Related U.S. Application Data
(60) Provisional application No. 63/774,574, filed on Mar. 19, 2025.
(60) Provisional application No. 63/966,471, filed on Jan. 23, 2026.

(51) Int. Cl. H03F 1/32; H03F 1/02; H03F 1/56; H03F 3/24; H04B 1/04

(52) U.S. Cl. CPC H03F 1/3247; H03F 1/0227; H03F 1/565; H03F 3/245; H04B 1/0475; H03F 2200/102; H03F 2200/451

(57) ABSTRACT

Apparatus and methods for delay calibration of load modulated power amplifiers and envelope trackers are disclosed herein. In certain embodiments, a load modulated power amplifier system includes a power amplifier that receives a radio frequency (RF) signal at an input, a controllable load impedance coupled to an output of the power amplifier and having an impedance modulated by an envelope control signal, and a calibration circuit that selects a time delay for aligning the envelope control signal to the RF signal. The time delay is selected based at least partly on an error vector magnitude (EVM) detected at the output of the power amplifier.

### CROSS-REFERENCE TO RELATED APPLICATIONS

This application claims the benefit of priority under 35 U.S.C. § 119 of U.S. Provisional Patent Application No. 63/966,471, filed Jan. 23, 2026, and titled “APPARATUS AND METHODS FOR DELAY CALIBRATION OF LOAD MODULATED POWER AMPLIFIERS AND ENVELOPE TRACKERS,” and of U.S. Provisional Patent Application No. 63/774,574, filed Mar. 19, 2025, and titled “APPARATUS AND METHODS FOR DELAY CALIBRATION OF LOAD MODULATED POWER AMPLIFIERS,” each of which is herein incorporated by reference in its entirety.

### BACKGROUND

### Field

Embodiments of the invention relate to electronic systems, and in particular, to radio frequency (RF) electronics.

### Description of the Related Technology

Power amplifiers are used in RF communication systems to amplify RF signals for transmission via antennas.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. RF signals have a frequency in the range from about 30 kHz to 300 GHz, for instance, in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

### SUMMARY

In certain embodiments, a load modulated power amplifier system is provided. The load modulated power amplifier includes a power amplifier configured to receive a radio frequency signal at an input and to provide an amplified radio frequency signal at an output, a controllable load impedance coupled to the output of the power amplifier and having an impedance modulated by an envelope control signal, and a calibration circuit configured to select a time delay for aligning the envelope control signal to the radio frequency signal, the time delay selected based at least partly on an error vector magnitude detected at the output of the power amplifier.

In some embodiments, the calibration circuit is configured to perform a coarse calibration based on the error vector magnitude detected at the output of the power amplifier followed by a fine calibration based on an adjacent channel leakage ratio detected at the output of the power amplifier.

In various embodiments, the load modulated power amplifier system further includes a power management circuit configured to control a voltage level of a power amplifier supply voltage of the power amplifier.

In several embodiments, the load modulated power amplifier system further includes a digital-to-analog converter configured to generate an analog transmit signal based on a digital transmit signal and a signal modulator configured to generate the radio frequency signal based on the digital transmit signal. According to a number of embodiments, the time delay controls a relative delay between the digital transmit signal and a digital representation of the envelope control signal.

In various embodiments, the load modulated power amplifier system further includes a directional coupler coupled to the output of the power amplifier and configured to generate a sensed signal, and an observation receiver configured to generate an observation signal for the calibration circuit based on the sensed signal. According to a number of embodiments, the load modulated power amplifier system further includes a baseband processor that includes the calibration circuit, the baseband processor configured to perform computations of the error vector magnitude based on the observation signal.

In several embodiments, the calibration circuit is configured to periodically calibrate the time delay during operation of the power amplifier.

In some embodiments, the calibration circuit is configured to calibrate the time delay to account for a change in one or more of a temperature of the power amplifier, a voltage standing wave ratio, or a frequency of the radio frequency signal.

In various embodiments, the envelope control signal changes in relation to an envelope of the radio frequency signal.

In certain embodiments, the present disclosure relates to a mobile device. The mobile device includes a front end system including a power amplifier configured to receive a radio frequency signal at an input and to provide an amplified radio frequency signal at an output, and a controllable load impedance coupled to the output of the power amplifier and having an impedance that is modulated by an envelope control signal. The mobile device further includes a baseband processor including a calibration circuit configured to select a time delay for aligning the envelope control signal to the radio frequency signal, the time delay selected based at least partly on an error vector magnitude detected at the output of the power amplifier.

In various embodiments, the calibration circuit is configured to perform a coarse calibration based on the error vector magnitude detected at the output of the power amplifier followed by a fine calibration based on an adjacent channel leakage ratio detected at the output of the power amplifier.

In several embodiments, the mobile device further includes a power management circuit configured to control a voltage level of a power amplifier supply voltage of the power amplifier.

In some embodiments, the mobile device further includes a transceiver including a digital-to-analog converter configured to generate an analog transmit signal based on a digital transmit signal and a signal modulator configured to generate the radio frequency signal based on the digital transmit signal. According to a number of embodiments, the time delay controls a relative delay between the digital transmit signal and a digital representation of the envelope control signal.

In various embodiments, the front-end system further includes a directional coupler coupled to the output of the power amplifier and configured to generate a sensed signal, the mobile device further comprising an observation receiver configured to generate an observation signal for the calibration circuit based on the sensed signal, the baseband processor is configured to perform computations of the error vector magnitude based on the observation signal.

In several embodiments, the calibration circuit is configured to periodically calibrate the time delay during operation of the power amplifier.

In some embodiments, the calibration circuit is configured to calibrate the time delay to account for a change in one or more of a temperature of the power amplifier, a voltage standing wave ratio, or a frequency of the radio frequency signal.

In various embodiments, the envelope control signal changes in relation to an envelope of the radio frequency signal.

In certain embodiments, the present disclosure relates to a method of power amplification in a mobile device. The method includes receiving a radio frequency signal at an input to a power amplifier and providing an amplified radio frequency signal at an output of the power amplifier, modulating an impedance of a controllable load impedance coupled to the output of the power amplifier using an envelope control signal, and selecting a time delay for aligning the envelope control signal to the radio frequency signal using a calibration circuit, the time delay selected based at least partly on an error vector magnitude detected at the output of the power amplifier.

In some embodiments, selecting the time delay comprises performing a coarse calibration based on the error vector magnitude detected at the output of the power amplifier followed by performing a fine calibration based on an adjacent channel leakage ratio detected at the output of the power amplifier.

In several embodiments, the method further includes controlling a voltage level of a power amplifier supply voltage of the power amplifier using a power management circuit.

In various embodiments, the method further includes generating an analog transmit signal based on a digital transmit signal using a digital-to-analog converter, and generating the radio frequency signal based on the digital transmit signal using a signal modulator. According to a number of embodiments, the time delay controls a relative delay between the digital transmit signal and a digital representation of the envelope control signal.

In some embodiments, the method further includes generating a sensed signal by sensing an output of the power amplifier using a directional coupler and generating an observation signal for the calibration circuit based on the sensed signal using an observation receiver. According to a number of embodiments, the method further includes performing computations of the error vector magnitude based on the observation signal.

In various embodiments, the method further includes periodically calibrating the time delay during operation of the power amplifier.

In several embodiments, the method further includes calibrating the time delay to account for a change in one or more of a temperature of the power amplifier, a voltage standing wave ratio, or a frequency of the radio frequency signal.

In some embodiments, the envelope control signal changes in relation to an envelope of the radio frequency signal.

In certain embodiments, a mobile device is disclosed. The mobile device includes a front-end system including a power amplifier module configured to receive a radio frequency signal and an envelope control signal indicating an envelope of the radio frequency signal, the power amplifier module including a power amplifier configured to amplify the radio frequency signal. The mobile device further includes a baseband processor including a calibration circuit configured to select a time delay for aligning the envelope control signal to the radio frequency signal, the time delay selected based at least partly on an error vector magnitude detected at the output of the power amplifier.

In various embodiments, the calibration circuit is configured to perform a coarse calibration based on the error vector magnitude detected at the output of the power amplifier followed by a fine calibration based on an adjacent channel leakage ratio detected at the output of the power amplifier.

In some embodiments, the mobile device further includes a transceiver including a digital-to-analog converter configured to generate an analog transmit signal based on a digital transmit signal and a signal modulator configured to generate the radio frequency signal based on the digital transmit signal. According to a number of embodiments, the time delay controls a relative delay between the digital transmit signal and a digital representation of the envelope control signal.

In several embodiments, the front-end system further includes a directional coupler coupled to the output of the power amplifier and configured to generate a sensed signal, the mobile device further comprising an observation receiver configured to generate an observation signal for the calibration circuit based on the sensed signal. According to a number of embodiments, the baseband processor is configured to perform computations of the error vector magnitude based on the observation signal.

In various embodiments, the calibration circuit is configured to periodically calibrate the time delay during operation of the power amplifier.

In some embodiments, the calibration circuit is configured to calibrate the time delay to account for a change in one or more of a temperature of the power amplifier, a voltage standing wave ratio, or a frequency of the radio frequency signal.

In several embodiments, the envelope control signal is operable to modulate a load of the power amplifier.

In various embodiments, the envelope control signal is operable to modulate a power supply voltage of the power amplifier.

In certain embodiments, a power amplifier system is disclosed. The power amplifier system includes a power amplifier module configured to receive a radio frequency signal and an envelope control signal indicating an envelope of the radio frequency signal, the power amplifier module including a power amplifier configured to amplify the radio frequency signal. The power amplifier system further includes a calibration circuit configured to select a time delay for aligning the envelope control signal to the radio frequency signal, the time delay selected based at least partly on an error vector magnitude detected at the output of the power amplifier.

In some embodiments, the calibration circuit is configured to perform a coarse calibration based on the error vector magnitude detected at the output of the power amplifier followed by a fine calibration based on an adjacent channel leakage ratio detected at the output of the power amplifier.

In various embodiments, the power amplifier system further includes a digital-to-analog converter configured to generate an analog transmit signal based on a digital transmit signal and a signal modulator configured to generate the radio frequency signal based on the digital transmit signal. According to a number of embodiments, the time delay controls a relative delay between the digital transmit signal and a digital representation of the envelope control signal.

In several embodiments, the front-end system further includes a directional coupler coupled to the output of the power amplifier and configured to generate a sensed signal, the power amplifier system further comprising an observation receiver configured to generate an observation signal for the calibration circuit based on the sensed signal. According to a number of embodiments, the power amplifier system further includes a baseband processor including the calibration circuit, the baseband processor configured to perform computations of the error vector magnitude based on the observation signal.

In several embodiments, the calibration circuit is configured to periodically calibrate the time delay during operation of the power amplifier.

In various embodiments, the calibration circuit is configured to calibrate the time delay to account for a change in one or more of a temperature of the power amplifier, a voltage standing wave ratio, or a frequency of the radio frequency signal.

In some embodiments, the envelope control signal is operable to modulate a load of the power amplifier.

In several embodiments, the envelope control signal is operable to modulate a power supply voltage of the power amplifier.

In certain embodiments, a method of power amplification in a mobile device is disclosed. The method includes receiving, as inputs to a power amplifier module, a radio frequency signal and an envelope control signal indicating an envelope of the radio frequency signal, amplifying the radio frequency signal using a power amplifier of the power amplifier module, and selecting a time delay for aligning the envelope control signal to the radio frequency signal using a calibration circuit, the time delay selected based at least partly on an error vector magnitude detected at the output of the power amplifier.

In several embodiments, selecting the time delay comprises performing a coarse calibration based on the error vector magnitude detected at the output of the power amplifier followed by performing a fine calibration based on an adjacent channel leakage ratio detected at the output of the power amplifier.

In some embodiments, the method further includes generating an analog transmit signal based on a digital transmit signal using a digital-to-analog converter and generating the radio frequency signal based on the digital transmit signal using a signal modulator. According to a number of embodiments, the time delay controls a relative delay between the digital transmit signal and a digital representation of the envelope control signal.

In several embodiments, the method further includes generating a sensed signal based on sensing the output of the power amplifier using a directional coupler, and generating an observation signal for the calibration circuit based on the sensed signal using an observation receiver. According to a number of embodiments, the method further includes performing computations of the error vector magnitude based on the observation signal.

In various embodiments, the method further includes periodically calibrating the time delay during operation of the power amplifier.

In some embodiments, the method further includes calibrating the time delay to account for a change in one or more of a temperature of the power amplifier, a voltage standing wave ratio, or a frequency of the radio frequency signal.

In various embodiments, the method further includes using the envelope control signal to modulate a load of the power amplifier.

In several embodiments, the method further includes using the envelope control signal to modulate a power supply voltage of the power amplifier.

In certain embodiments, an envelope tracking system is provided. The envelope tracking system includes a power amplifier configured to receive a radio frequency signal at an input and to provide an amplified radio frequency signal at an output, the power amplifier further configured to receive a power amplifier supply voltage. The envelope tracking system further includes an envelope tracker configured to control a voltage level of the power amplifier supply voltage based on an envelope control signal indicating an envelope of the radio frequency signal, and a calibration circuit configured to select a time delay for aligning the envelope control signal to the radio frequency signal, the time delay selected based at least partly on an error vector magnitude detected at the output of the power amplifier.

In various embodiments, the calibration circuit is configured to perform a coarse calibration based on the error vector magnitude detected at the output of the power amplifier followed by a fine calibration based on an adjacent channel leakage ratio detected at the output of the power amplifier.

In some embodiments, the envelope tracking system further includes a digital-to-analog converter configured to generate an analog transmit signal based on a digital transmit signal and a signal modulator configured to generate the radio frequency signal based on the digital transmit signal. According to a number of embodiments, the time delay controls a relative delay between the digital transmit signal and a digital representation of the envelope control signal.

In various embodiments, the envelope tracking system further includes a directional coupler coupled to the output of the power amplifier and configured to generate a sensed signal, and an observation receiver configured to generate an observation signal for the calibration circuit based on the sensed signal. According to a number of embodiments, the envelope tracking system further includes a baseband processor that includes the calibration circuit, the baseband processor configured to perform computations of the error vector magnitude based on the observation signal.

In several embodiments, the calibration circuit is configured to periodically calibrate the time delay during operation of the power amplifier.

In various embodiments, the calibration circuit is configured to calibrate the time delay to account for a change in one or more of a temperature of the power amplifier, a voltage standing wave ratio, or a frequency of the radio frequency signal.

In certain embodiments, the present disclosure relates to a mobile device. The mobile device includes a front end system including a power amplifier configured to receive a radio frequency signal at an input and to provide an amplified radio frequency signal at an output, the power amplifier further configured to receive a power amplifier supply voltage. The mobile device further includes a power management system including an envelope tracker configured to control a voltage level of the power amplifier supply voltage based on an envelope control signal indicating an envelope of the radio frequency signal, and a baseband processor including a calibration circuit configured to select a time delay for aligning the envelope control signal to the radio frequency signal, the time delay selected based at least partly on an error vector magnitude detected at the output of the power amplifier.

In various embodiments, the calibration circuit is configured to perform a coarse calibration based on the error vector magnitude detected at the output of the power amplifier followed by a fine calibration based on an adjacent channel leakage ratio detected at the output of the power amplifier.

In some embodiments, the mobile device further includes a transceiver including a digital-to-analog converter configured to generate an analog transmit signal based on a digital transmit signal and a signal modulator configured to generate the radio frequency signal based on the digital transmit signal. According to a number of embodiments, the time delay controls a relative delay between the digital transmit signal and a digital representation of the envelope control signal.

In several embodiments, the front-end system further includes a directional coupler coupled to the output of the power amplifier and configured to generate a sensed signal, the mobile device further comprising an observation receiver configured to generate an observation signal for the calibration circuit based on the sensed signal. According to a number of embodiments, the baseband processor is configured to perform computations of the error vector magnitude based on the observation signal.

In various embodiments, the calibration circuit is configured to periodically calibrate the time delay during operation of the power amplifier.

In several embodiments, the calibration circuit is configured to calibrate the time delay to account for a change in one or more of a temperature of the power amplifier, a voltage standing wave ratio, or a frequency of the radio frequency signal.

In certain embodiments, a method of power amplification in a mobile device is disclosed. The method includes receiving a radio frequency signal at an input to a power amplifier and providing an amplified radio frequency signal at an output of the power amplifier, controlling a voltage level of the power amplifier supply voltage based on an envelope control signal using an envelope tracker, the envelope control signal indicating an envelope of the radio frequency signal, and selecting a time delay for aligning the envelope control signal to the radio frequency signal using a calibration circuit, the time delay selected based at least partly on an error vector magnitude detected at the output of the power amplifier.

In various embodiments, selecting the time delay comprises performing a coarse calibration based on the error vector magnitude detected at the output of the power amplifier followed by performing a fine calibration based on an adjacent channel leakage ratio detected at the output of the power amplifier.

In several embodiments, the method further includes generating an analog transmit signal based on a digital transmit signal using a digital-to-analog converter, and generating the radio frequency signal based on the digital transmit signal using a signal modulator. According to a number of embodiments, the time delay controls a relative delay between the digital transmit signal and a digital representation of the envelope control signal.

In some embodiments, the method further includes generating a sensed signal by sensing an output of the power amplifier using a directional coupler and generating an observation signal for the calibration circuit based on the sensed signal using an observation receiver. According to a number of embodiments, the method further includes performing computations of the error vector magnitude based on the observation signal.

In various embodiments, the method further includes periodically calibrating the time delay during operation of the power amplifier.

In several embodiments, the method further includes calibrating the time delay to account for a change in one or more of a temperature of the power amplifier, a voltage standing wave ratio, or a frequency of the radio frequency signal.

### BRIEF DESCRIPTION OF THE DRAWINGS

Embodiments of this disclosure will now be described, by way of non-limiting example, with reference to the accompanying drawings.

FIG. 1 is a schematic diagram of one embodiment of a load modulated power amplifier.

FIG. 2 is a schematic diagram of another embodiment of a load modulated power amplifier.

FIG. 3 is a schematic diagram of one embodiment of a load modulated power amplifier system.

FIG. 4A is a schematic diagram of another embodiment of a load modulated power amplifier system.

FIG. 4B is a schematic diagram of another embodiment of a load modulated power amplifier system.

FIG. 5 is a schematic diagram of one embodiment of a delay calibration.

FIG. 6A is a graph of one example of adjacent channel leakage ratio (ACLR) during a delay search for a delay calibration.

FIG. 6B is a graph of one example of ACLR versus delay for a delay calibration.

FIG. 7 is a graph of one example of ACLR and error vector magnitude (EVM) versus delay for a delay calibration.

FIG. 8 is a schematic diagram of one embodiment of a mobile device.

FIG. 9 is a schematic diagram of a load modulated power amplifier system according to another embodiment.

FIG. 10A is a schematic diagram of one embodiment of a packaged module.

FIG. 10B is a schematic diagram of a cross-section of the packaged module of FIG. 10A taken along the lines 10B-10B.

FIG. 11 is a schematic diagram of another embodiment of a communication system for transmitting radio frequency (RF) signals.

FIG. 12 is a schematic diagram of a multi-level supply (MLS) modulation system according to one embodiment.

FIG. 13 is a schematic diagram of an MLS DC-to-DC converter according to one embodiment.

FIG. 14 is a schematic diagram of an envelope tracking system according to another embodiment.

FIG. 15 is a schematic diagram of an envelope tracking system according to another embodiment.

FIG. 16A shows a first example of a power amplifier supply voltage versus time.

FIG. 16B shows a second example of a power amplifier supply voltage versus time.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

### Overview of Calibration of Load Modulated Power Amplifiers and Envelope Trackers

A load modulated power amplifier can include a power amplifier that amplifies a radio frequency (RF) input signal and a load impedance coupled to an output of the power amplifier and that is modulated based on an envelope of the RF input signal. Providing load impedance modulation in this manner provides high efficiency over a wide dynamic range.

In certain implementations, the load impedance includes an output balun having a first winding and a second winding that are electromagnetically coupled to one another. Additionally, the output of the power amplifier is coupled to a first terminal of the first winding (or in a push-pull configuration with a pair of outputs coupled to first and second terminals of the first winding), while an amplified RF signal is outputted from a first terminal of the second winding. The load impedance further includes a controllable capacitor coupled to a second terminal of the second winding (for instance, electrically connected between the second terminal and ground) and having a capacitance controlled by the envelope of the RF signal.

Thus, load modulation can be performed by sweeping an impedance of a termination capacitor on the secondary port of the balun.

In comparison to power amplifiers in which an envelope tracker controls a supply voltage of the power amplifier to track an envelope control signal, load modulated power amplifiers have a load impedance controlled based on the envelope control signal. Providing load modulation in this manner provides higher efficiency power amplifiers that are less complex than envelope tracking power amplifiers, while leveraging circuitry for generating and calibrating the envelope control signal for desired performance.

For example, a load modulated power amplifier can be powered by a high efficiency DC-to-DC converter, for instance, a power management unit (PMU) operating with an efficiency of 93% or higher. Such a PMU can, for instance, operate using average power tracking (APT) over 5.5V+2.5-3.0V (power amplifier efficiency can be better at higher supply voltage due to non-zero knee voltage). In contrast, an envelope tracking system may have only 80% efficiency, with the supply voltage~2.5-3.0V (power amplifier efficiency can be worse at lower supply voltage due to non-zero knee voltage). A PMU is also referred to herein as a power management circuit or a power management integrated circuit (PMIC).

Aspects of the present disclosure relate to delay calibration schemes for calibrating the delay of an envelope signal relative to an RF signal. The delay calibration techniques disclosed herein are applicable both to load modulated power amplifiers in which the envelope signal provides load modulation, and to envelope tracking systems in which the envelope signal controls a voltage level of a power amplifier supply voltage of a power amplifier.

Load modulated power amplifiers and envelope trackers can be included in a wide variety of RF communication systems, including, but not limited to, base stations, network access points, mobile phones, tablets, customer-premises equipment (CPE), laptops, computers, wearable electronics, and/or other communication devices.

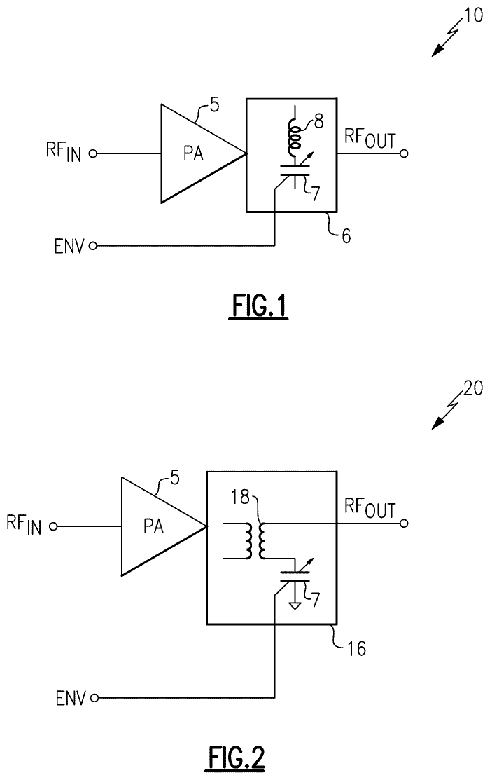

FIG. 1 is a schematic diagram of one embodiment of a load modulated power amplifier 10. The load modulated power amplifier 10 includes a power amplifier 5 and a controllable load impedance 6. The load modulated power amplifier 10 amplifies an RF input signal RF_{IN} to generate an RF output signal RF_{OUT}.

The load modulated power amplifier 10 receives an envelope control signal ENV that changes in relation to an envelope of the RF input signal RF_{IN}. The envelope control signal ENV is used to control an impedance of the controllable load impedance 6. For example, in this embodiment, the controllable load impedance 6 includes a series combination of an inductor 8 and a controllable capacitor 7, and the envelope control signal ENV is used to control a capacitance of the controllable capacitor 7. Although one example of a controllable load impedance is depicted, the teachings herein are applicable to other implementations of controllable load impedances.

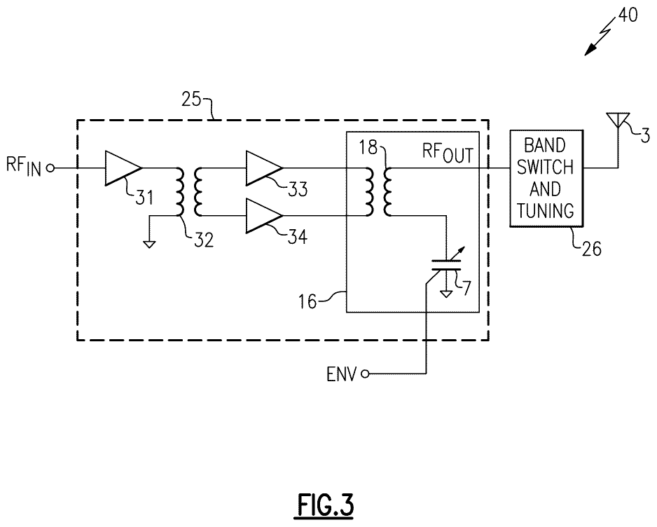

FIG. 2 is a schematic diagram of another embodiment of a load modulated power amplifier 20. The load modulated power amplifier 20 of FIG. 2 is similar to the load modulated power amplifier 10 of FIG. 1, except that the load modulated power amplifier 20 of FIG. 2 includes a different implementation of a controllable load impedance 16.

In particular, the controllable load impedance 16 includes a balun 18 and a controllable capacitor 7. An output of the power amplifier 5 drives a first winding of the balun 18. Additionally, a first terminal of a second winding of the balun 18 outputs the RF output signal RF_{OUT}, while a second terminal of the second winding is coupled to the controllable capacitor 7. The controllable capacitor 7 is controlled by the envelope control signal ENV.

Changing a value of the controllable capacitor 7 effectively resonates out some of the inductance of the second winding, thereby effectively changing a turn ratio of the balun 18.

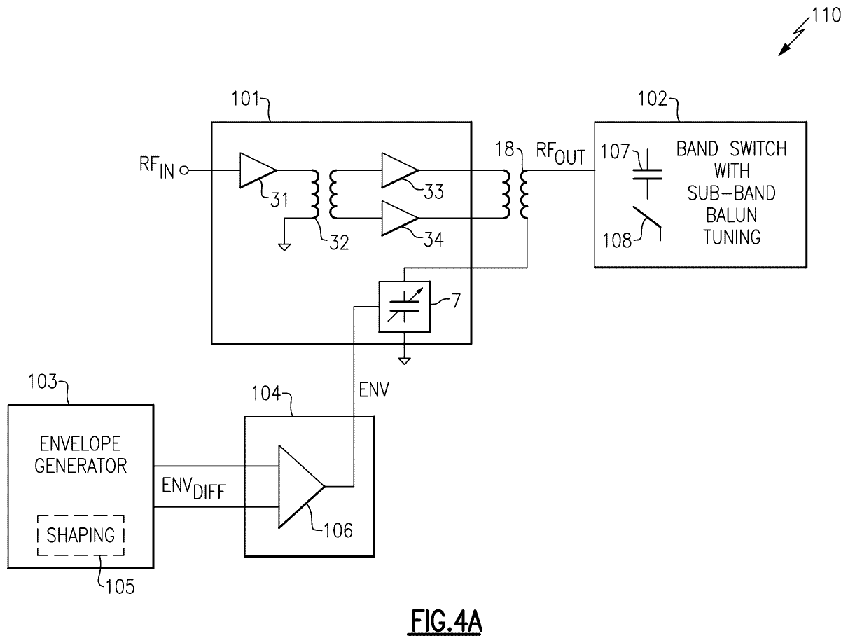

FIG. 3 is a schematic diagram of one embodiment of a load modulated power amplifier system 40. The load modulated power amplifier system 40 includes a load modulated power amplifier 25, a band switch and tuning circuit 26, and an antenna 3.

In the illustrated embodiment, the load modulated power amplifier 25 includes a driver amplifier 31, an input balun 32, a first output amplifier 33, a second output amplifier 34, and a controllable load impedance 16 that includes an output balun 18 and a controllable capacitor 7.

The load modulated power amplifier 25 is implemented as a push-pull amplifier, in this embodiment. Additionally, an output of the first output amplifier 33 is connected to a first terminal of a first winding of the balun 18, while an output of the second output amplifier 34 is connected to a second terminal of the first winding of the balun 18.

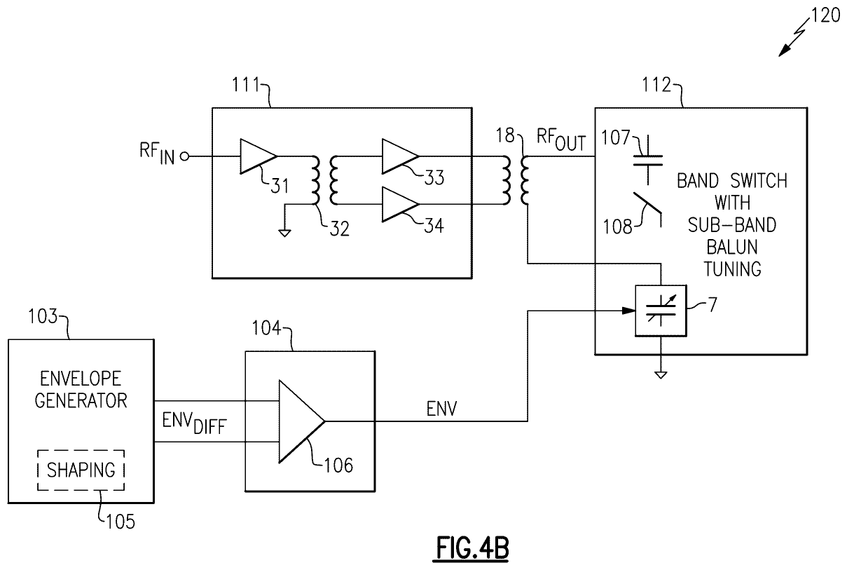

FIG. 4A is a schematic diagram of another embodiment of a load modulated power amplifier system 110. The load modulated power amplifier system 110 includes an output balun 18, a power amplifier die 101, a switch die 102, an envelope generator die 103, and a driver die 104. The power amplifier die 101 includes a driver amplifier 31, an input balun 32, a first output amplifier 33, a second output amplifier 34, and a controllable capacitor 7. The switch die 102 includes a capacitor 107 and a switch 108. Furthermore, the envelope generator die 103 includes a shaping circuit 105 for shaping a differential envelope control signal ENV_{DIFF} provided to the driver die 104. The driver die 104 includes an amplifier 106 for receiving the differential envelope control signal ENV_{DIFF}, and that outputs an envelope control signal ENV for controlling the controllable capacitor 7.

The load modulated power amplifier system 110 can operate with system level calibration for aligning and shaping the envelope control signal for the controllable capacitor 7 to the RF input signal amplified by the push-pull amplifier. The envelope calibration can be implemented in accordance with any of the embodiments herein.

FIG. 4B is a schematic diagram of another embodiment of a load modulated power amplifier system 120. The load modulated power amplifier system 120 includes an output balun 18, a power amplifier die 111, a switch die 112, an envelope generator die 103, and a driver die 104.

The load modulated power amplifier system 120 of FIG. 4B is similar to the load modulated power amplifier system 110 of FIG. 4A, except that the load modulated power amplifier system 120 illustrates an implementation in which the controllable capacitor 7 is on the switch die 112. Since the switch die 112 is typically implemented using a silicon on insulator (SOI) process and the power amplifier die 111 using a compound semiconductor process (for instance, GaAs), placing the controllable capacitor 7 on the switch die 112 aids in providing a high quality-factor (Q-factor) capacitor.

### Example Embodiments for Delay Calibration

As discussed above, load modulated power amplifiers provide the ability to modulate the power amplifier load and eliminate complex envelope tracking power supply content. Using this technology, the system can use signal envelope information to dynamically modulate the amplifier load to provide improved efficiency. Load modulation provides reduced power supply complexity and/or wider bandwidth operation.

For load modulated power amplifiers to operate efficiently, calibration techniques are needed to properly modulate the amplifier load synchronous with the RF signal's envelope.

In certain load modulated power amplifier applications, it is desirable to align the envelope control signal to the RF signal to achieve low ACLR. To provide such alignment, ACLR can be observed over multiple delay settings for controlling relative delay between the envelope control signal and the RF signal, and the delay setting with the lowest ACLR can be selected.

For example, such a calibration can be performed periodically or as desired during operation of the load modulated power amplifier system to provide calibration that accounts for operating conditions and/or other variations. For instance, a desired delay setting can change based on temperature, voltage standing wave ratio (VSWR), signal frequency (including the signal channel with a given frequency band), and/or other operating parameters.

Although such calibration is desired to achieve low ACLR, measuring ACLR is relatively time consuming. Thus, performance of the load modulated power amplifier system can be poor while the system is performing a relatively slow search for the desired delay setting.

Furthermore, for envelope trackers to operate efficiently, calibration techniques are also needed to properly modulate the amplifier's power supply synchronous with the RF signal's envelope.

Apparatus and methods for delay calibration of load modulated power amplifiers and envelope trackers are disclosed herein.

In a first aspect, a load modulated power amplifier system includes a power amplifier that receives an RF signal at an input and provides an amplified RF signal at an output, a controllable load impedance coupled to the output of the power amplifier and having an impedance modulated by an envelope control signal, and a calibration circuit that selects a time delay for aligning the envelope control signal to the RF signal. The time delay is selected based at least partly on an error vector magnitude (EVM) detected at the output of the power amplifier. For example, in certain implementations, the calibration circuit performs an initial coarse calibration of the time delay based on EVM detected at the power amplifier's output, followed by a fine calibration of the time delay based on ACLR detected at the power amplifier's output.

By implementing the load modulated power amplifier in this manner, faster delay calibration can be achieved. For example, the EVM calibration can set the delay relatively close to a delay window associated with desired ACLR performance. Such initial calibration can be performed quickly, since EVM measurements can be performed much more quickly (for instance, with less computational complexity) than ACLR measurements. Thereafter, a fine calibration can be performed based on ACLR measurements to achieve more accurate delay calibration.

The fast calibration not only allows the system to quickly determine the appropriate delay setting for the current operational parameters but also mitigates degradations in link performance that can arise during a long searching process.

In a second aspect, an envelope tracker controls a power supply voltage of a power amplifier based on an envelope control signal corresponding to an envelope of a radio frequency signal amplified by the power amplifier. Additionally, a calibration circuit selects a time delay for aligning the envelope control signal to the radio frequency signal, the time delay selected based at least partly on an EVM detected at the output of the power amplifier.

By implementing the envelope tracking system in this manner, faster delay calibration can be achieved. For example, the EVM calibration can set the delay relatively close to a delay window associated with desired ACLR performance.

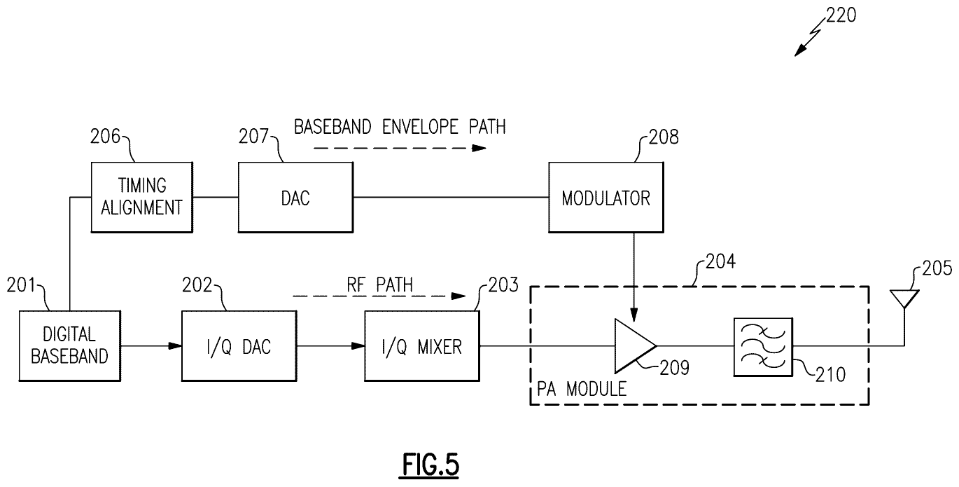

FIG. 5 is a schematic diagram of one embodiment of a delay calibration for a power amplifier system 220. The power amplifier system 220 includes a digital baseband circuit 201, an in-phase/quadrature-phase (I/Q) digital-to-analog converter (DAC) 202, an I/Q mixer 203, a power amplifier module 204, an antenna 205, a timing alignment circuit 206, an envelope path DAC 207, and a modulator 208. The power amplifier module 204 includes a power amplifier 209 and a power amplifier filter 210, in this embodiment.

The modulator 208 can correspond to either a load modulator (for implementations in which the power amplifier 209 is a load modulated power amplifier having a load impedance controlled by the modulator 208) or to a supply voltage modulator (for implementations in which the power amplifier 209 has a supply voltage controlled by the modulator 208).

As shown in FIG. 5, the digital baseband circuit 201 (which can be part of a baseband processor, in some implementations) generates a digital transmit signal as well as a digital envelope control signal.

In the illustrated embodiment, the digital transmit signal is provided to the I/Q DAC 202 to generate an analog I/Q transmit signal. The I/Q mixer 203 upconverts to the analog I/Q transmit signal to an RF signal that is provided to the power amplifier 209 for amplification. The digital envelope control signal is provided to a timing alignment circuit 206 (which can be part of a baseband processor, in some implementations), which depicts one implementation of a delay calibration circuit. The timing alignment circuit 206 controls a delay of the digital envelope control signal relative to the digital transmit signal. The time-aligned digital envelope control signal is provided to the envelope path DAC 207, which generates an analog envelope control signal that is used by the modulator 208 to control modulation (load modulation or supply voltage modulation, based on implementation) of the power amplifier 209.

Although the illustrated embodiment shows the timing alignment circuit 206 in the envelope path, the teachings herein are also applicable to configurations in which a timing alignment circuit is in the transmit signal path and/or in both the envelope path and the transmit signal path. Thus, any delay control can be used to control the timing alignment between the RF signal and the envelope control signal for providing modulation.

For best ACLR, is desirable for the baseband envelope path and the RF path to have optimum or near optimum delay alignment. For example, it can be desirable for the delay setting to be within a time window associated with excellent ACLR performance.

ACLR is a function of timing alignment between the baseband envelope path and the RF path. For wideband waveforms (for example, of 100 MHz bandwidth or more), ACLR varies significantly as a function of timing window.

The time required to search for best ACLR can be large and will result in degraded link performance until ACLR calibration is achieved.

To address such degradations, the timing alignment circuit 206 selects a time delay for aligning the envelope control signal to the RF signal based at least partly on an EVM detected at the output of the power amplifier 209. For example, in certain implementations, the timing alignment circuit 206 performs an initial coarse calibration of the time delay based on EVM detected at the power amplifier's output, followed by a fine calibration of the time delay based on ACLR detected at the power amplifier's output.

For example, in some embodiments herein calibration is performed by first using time domain EVM measurements to obtain an estimate of the desired delay setting (for example, a delay seed value), and then using the estimated delay setting delay from the EVM measurements as a starting point for a fine search for the best ACLR time window.

Such calibration achieves fast calibration time, since EVM can be computed more quickly than ACLR (for instance, 2 ms for a single EVM measurement versus 6 ms for a single ACLR measurement). For example, reductions in search time of 30% or more can be achieved using such a technique.

The fast calibration not only allows the system to quickly determine the appropriate delay setting for the current operational parameters but also mitigates degradations in link performance that can arise during a long searching process.

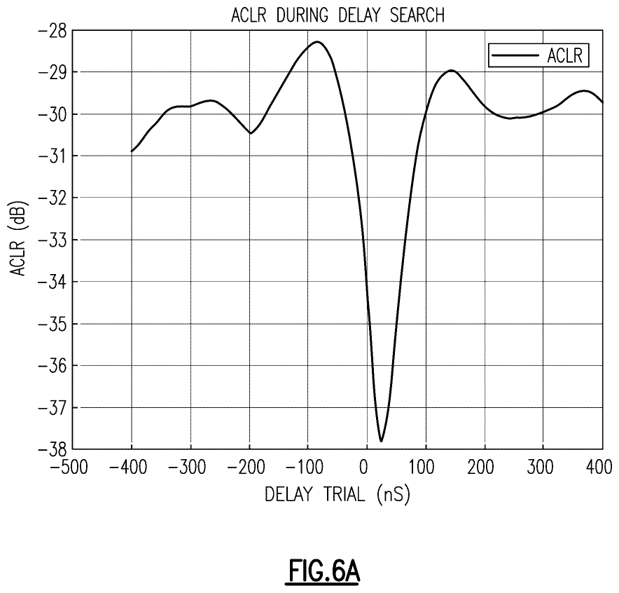

FIG. 6A is a graph of one example of ACLR during a delay search for a delay calibration. The example graph depicts ACLR for a 5 MHz waveform, in which local minima on the ACLR curve is observed every 200 ns.

Since ACLR is the result of non-linear behavior of a power amplifier, the ACLR curve versus delay is non-monotonic, with the presence of local nulls in the ACLR versus delay curve presenting a challenge to derive the direction of search in a convergence algorithm.

EVM is a more direct measurement of the average fit between the envelope path and the RF amplitude which result is a linear convolution. It is observed that the EVM versus delay curve presents a single null, therefore allowing for a directional search.

Such differences in the characteristics of EVM versus ACLR allow for a coarse tuning of the delay setting based on EVM, followed by a fine tuning of the delay setting based on ACLR.

FIG. 6B is a graph of one example of ACLR versus delay for a delay calibration. The graph depicts ACLR over a small delay window and thus does not show various local nulls as in FIG. 6A.

As shown in FIG. 6B, a narrow time window can be needed for a best ACLR time window.

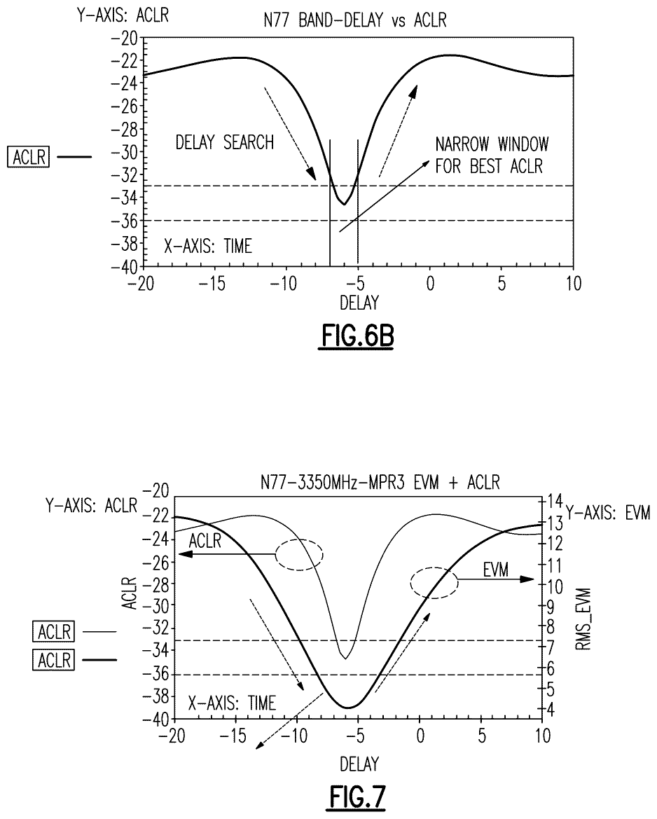

FIG. 7 is a graph of one example of ACLR and EVM versus delay for a delay calibration.

The graph depicts an example of a fast delay search (coarse search) to find EVM minima. After identifying the seed value from the EVM search, a fine search is performed to find best ACLR.

### Example Embodiments of Mobile Device, Packaged Module, and Envelope Trackers

Load modulated power amplifiers and/or envelope trackers can be included in a wide variety of RF communication systems. Examples of such RF communication systems include, but are not limited to, mobile phones, tablets, base stations, network access points, CPE, laptops, and wearable electronics. In certain implementations, a load modulated power amplifier and/or envelope tracker can be included on a semiconductor die of a module, which in turn can be attached to a circuit board of an RF communication system.

This section depicts examples of load modulated power amplifiers or envelope trackers that can be calibrated in accordance with any of the embodiments of envelope delay calibration disclosed herein. Further, various examples of RF electronics with load modulated power amplifiers or envelope trackers are provided. However, the teachings herein are applicable to RF electronics implemented in a wide variety of ways. Accordingly, other implementations are possible.

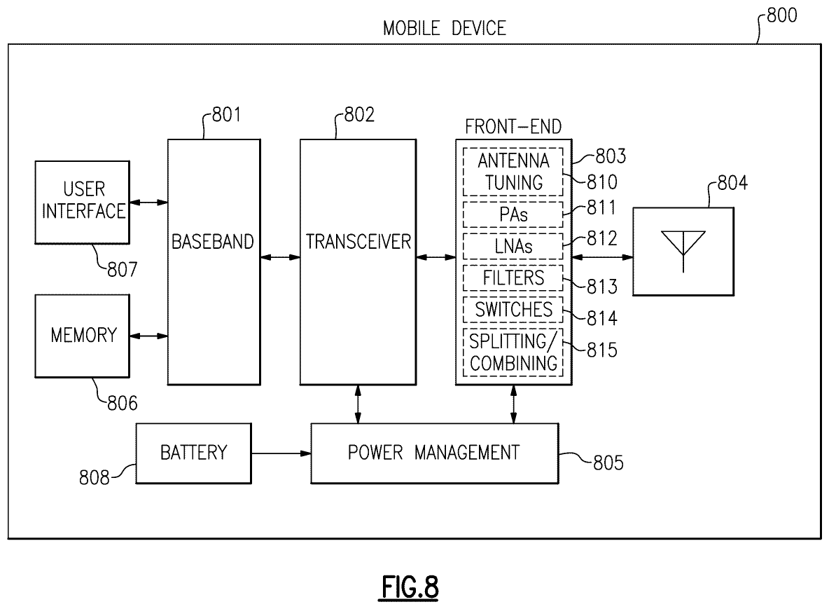

FIG. 8 is a schematic diagram of one embodiment of a mobile device 800. The mobile device 800 includes a baseband system 801, a transceiver 802, a front end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 8 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAs) 811, low noise amplifiers (LNAs) 812, filters 813, switches 814, and signal splitting/combining circuitry 815. However, other implementations are possible.

For example, the front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain embodiments, at least one of the power amplifiers 811 is implemented as a load modulated power amplifier in accordance with the teachings herein. In other embodiments, the power management system 805 is implemented with an envelope tracker in accordance with the teachings herein. Although the mobile device 800 illustrates one embodiment of a communication system that can be implemented with one or more load modulated power amplifiers or envelope trackers, the teachings herein are applicable to a wide range of systems. Accordingly, other implementations are possible.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 8, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE). In certain embodiments, the power management system 805 includes an envelope tracker calibrated in accordance with the teachings herein.

As shown in FIG. 8, the power management system 805 receives a battery voltage from the battery 808. The battery 808 can be any suitable battery for use in the mobile device 800, including, for example, a lithium-ion battery.

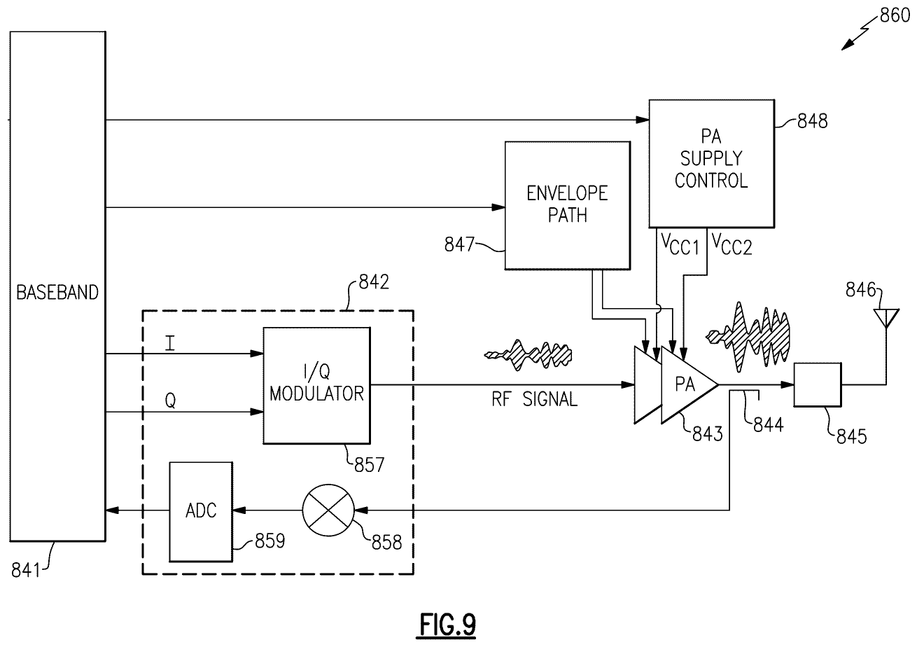

FIG. 9 is a schematic diagram of a load modulated power amplifier system 860 according to another embodiment.

The illustrated load modulated power amplifier system 860 includes a baseband processor 841, a transmitter/observation receiver 842, a load modulated power amplifier (PA) 843, a directional coupler 844, front-end circuitry 845, an antenna 846, an envelope path 847, and a PA supply control circuit 848. The illustrated transmitter/observation receiver 842 includes an I/Q modulator 857, a mixer 858, and an analog to digital converter (ADC) 859. In certain implementations, the transmitter/observation receiver 842 is incorporated into a transceiver.

The baseband processor 841 can be used to generate an in-phase (I) signal and a quadrature-phase (Q) signal, which can be used to represent a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals can be provided to the I/Q modulator 857 in a digital format. The baseband processor 841 can be any suitable processor configured to process a baseband signal. For instance, the baseband processor 841 can include a digital signal processor, a microprocessor, a programmable core, or any combination thereof. Moreover, in some implementations, two or more baseband processors 841 can be included in the load modulated power amplifier system 860.

The I/Q modulator 857 can be configured to receive the I and Q signals from the baseband processor 841 and to process the I and Q signals to generate an RF signal. For example, the I/Q modulator 857 can include digital-to-analog converters (DACs) configured to convert the I and Q signals into an analog format, mixers for upconverting the I and Q signals to RF, and a signal combiner for combining the upconverted I and Q signals into an RF signal suitable for amplification by the load modulated power amplifier 843. In certain implementations, the I/Q modulator 857 can include one or more filters configured to filter frequency content of signals processed therein.

The load modulated power amplifier 843 can receive the RF signal from the I/Q modulator 857, and when enabled can provide an amplified RF signal to the antenna 846 via the front-end circuitry 845. The load modulated power amplifier 843 can be implemented with any desired load modulation scheme.

The front-end circuitry 845 can be implemented in a wide variety of ways. In one example, the front-end circuitry 845 includes one or more switches, filters, duplexers, multiplexers, and/or other components. In another example, the front-end circuitry 845 is omitted in favor of the load modulated power amplifier 843 providing the amplified RF signal directly to the antenna 846.

The directional coupler 844 senses an output signal of the power amplifier 823. Additionally, the sensed output signal from the directional coupler 844 is provided to the mixer 858, which multiplies the sensed output signal by a reference signal of a controlled frequency. The mixer 858 operates to generate a downshifted signal by downshifting the sensed output signal's frequency content. The downshifted signal can be provided to the ADC 859, which can convert the downshifted signal to a digital format suitable for processing by the baseband processor 841.

Including a feedback path from the output of the load modulated power amplifier 843 to the baseband processor 841 allows for sensing EVM, sensing ACLR, providing power control, compensating for transmitter impairments, and/or performing digital pre-distortion (DPD). Although one example of a sensing path for a power amplifier is shown, other implementations are possible.

The PA supply control circuit 848 receives a power control signal from the baseband processor 841, and controls supply voltages of the load modulated power amplifier 843. In the illustrated configuration, the PA supply control circuit 848 generates a first supply voltage V_{CC1} for powering an input stage of the load modulated power amplifier 843 and a second supply voltage V_{CC2} for powering an output stage of the load modulated power amplifier 843. The PA supply control circuit 848 can control the voltage level of the first supply voltage V_{CC1} and/or the second supply voltage V_{CC2} to enhance the power amplifier system's PAE.

The PA supply control circuit 848 can employ various power management techniques to change the voltage level of one or more of the supply voltages over time to improve the power amplifier's power added efficiency (PAE), thereby reducing power dissipation. For example, one technique for improving efficiency of a power amplifier is average power tracking (APT), in which a DC-to-DC converter is used to generate a supply voltage for a power amplifier based on the power amplifier's average output power.

As shown in FIG. 9, the envelope path 847 receives an envelope control signal from the baseband processor 841, and controls load modulation of the load modulated power amplifier 843. The envelope path 847 can be calibrated in accordance with any of the delay calibration schemes herein.

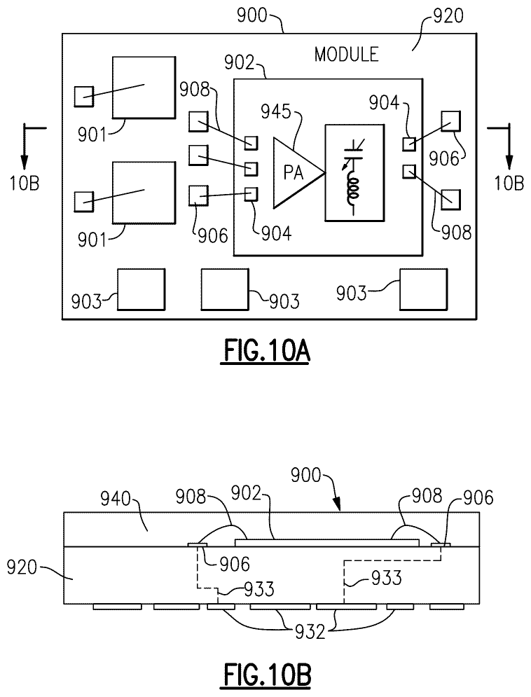

FIG. 10A is a schematic diagram of one embodiment of a packaged module 900. FIG. 10B is a schematic diagram of a cross-section of the packaged module 900 of FIG. 10A taken along the lines 10B-10B.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a load modulated power amplifier 945, which can be delay calibrated in accordance with any of the embodiments herein.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs).

As shown in FIG. 10B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 10B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

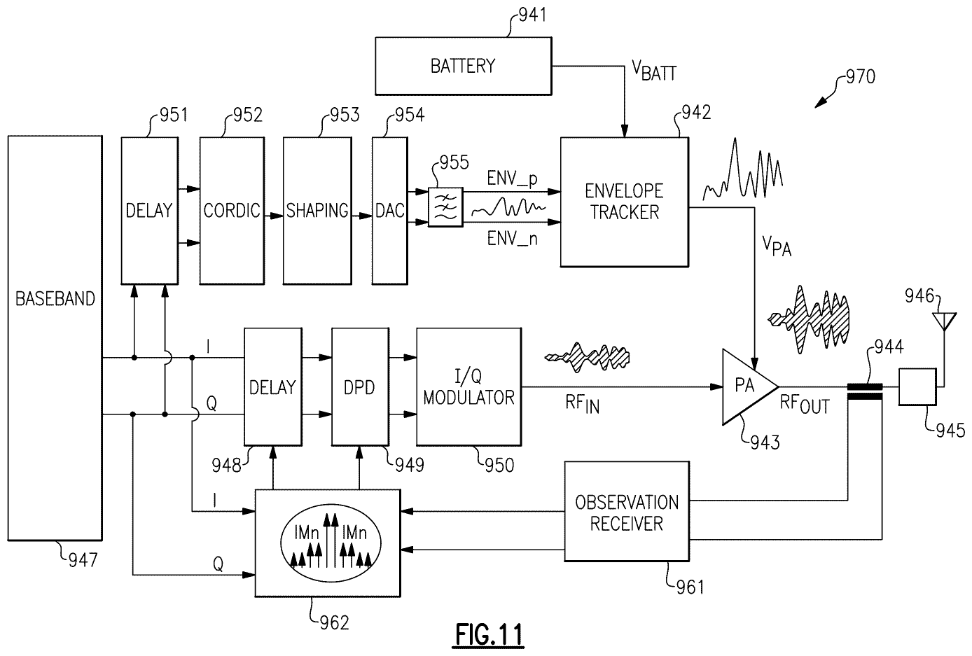

FIG. 11 is a schematic diagram of another embodiment of a communication system 970 for transmitting RF signals. The communication system 970 includes a battery 941, an envelope tracker 942, a power amplifier 943, a directional coupler 944, a duplexing and/or switching circuit 945, an antenna 946, a baseband processor 947, a signal delay circuit 948, a digital pre-distortion (DPD) circuit 949, an I/Q modulator 950, an observation receiver 961, an intermodulation detection circuit 962, an envelope delay circuit 951, a coordinate rotation digital computation (CORDIC) circuit 952, a shaping circuit 953, a digital-to-analog converter 954, and a reconstruction filter 955.

The communication system 970 of FIG. 11 illustrates one example of an RF system that can include an envelope tracking system calibrated in accordance with any of the delay calibration schemes disclosed herein. However, the teachings herein are applicable to envelope tracking systems implemented in a wide variety of ways.

The baseband processor 947 operates to generate an in-phase (I) signal and a quadrature-phase (Q) signal, which correspond to signal components of a sinusoidal wave or signal of a desired amplitude, frequency, and phase. For example, the I signal and the Q signal provide an equivalent representation of the sinusoidal wave. In certain implementations, the I and Q signals are outputted in a digital format. The baseband processor 947 can be any suitable processor for processing baseband signals. For instance, the baseband processor 947 can include a digital signal processor, a microprocessor, a programmable core, or any combination thereof.

The signal delay circuit 948 provides adjustable delay to the I and Q signals to aid in controlling relative alignment between the differential analog envelope signal ENV_p, ENV_n provided to the envelope tracker 942 and the RF signal RF_{IN} provided to the power amplifier 943. The amount of delay provided by the signal delay circuit 948 is controlled based on amount of intermodulation in adjacent bands detected by the intermodulation detection circuit 942.

The DPD circuit 949 operates to provide digital shaping to the delayed I and Q signals from the signal delay circuit 948 to generate digitally pre-distorted I and Q signals. In the illustrated embodiment, the DPD provided by the DPD circuit 949 is controlled based on amount of intermodulation detected by the intermodulation detection circuit 942. The DPD circuit 949 serves to reduce a distortion of the power amplifier 943 and/or to increase the efficiency of the power amplifier 943.

The I/Q modulator 950 receives the digitally pre-distorted I and Q signals, which are processed to generate the RF signal RF_{IN}. For example, the I/Q modulator 950 can include DACs configured to convert the digitally pre-distorted I and Q signals into an analog format, mixers for upconverting the analog I and Q signals to radio frequency, and a signal combiner for combining the upconverted I and Q signals into the RF signal RF_{IN}. In certain implementations, the I/Q modulator 950 can include one or more filters configured to filter frequency content of signals processed therein.

The envelope delay circuit 951 delays the I and Q signals from the baseband processor 947. Additionally, the CORDIC circuit 952 processes the delayed I and Q signals to generate a digital envelope signal representing an envelope of the RF signal RF_{IN}. Although FIG. 11 illustrates an implementation using the CORDIC circuit 952, an analog envelope signal can be obtained in other ways.

The shaping circuit 953 operates to shape the digital envelope signal to enhance the performance of the communication system 970. In certain implementations, the shaping circuit 953 includes a shaping table that maps each level of the digital envelope signal to a corresponding shaped envelope signal level. Envelope shaping can aid in controlling linearity, distortion, and/or efficiency of the power amplifier 953.

In the illustrated embodiment, the shaped envelope signal is a digital signal that is converted by the DAC 954 to a differential analog envelope signal. Additionally, the differential analog envelope signal is filtered by the reconstruction filter 955 to generate a differential analog envelope signal ENV_p, ENV_n for the envelope tracker 952. However, other implementations are possible including, but not limited to, implementations using single-ended envelope signals.

With continuing reference to FIG. 11, the envelope tracker 942 receives the differential analog envelope signal from the reconstruction filter 955 and a battery voltage V_{BATT} from the battery 941, and uses the differential analog envelope signal ENV_p, ENV_n to generate a power amplifier supply voltage V_{PA} for the power amplifier 943 that changes in relation to the envelope of the RF signal RF_{IN}. The power amplifier 943 receives the RF signal RF_{IN} from the I/Q modulator 950, and provides an amplified RF signal RF_{OUT} to the antenna 946 through the duplexing and switching circuit 945, in this example.

The directional coupler 944 is positioned between the output of the power amplifier 943 and the input of the duplexing and switching circuit 945, thereby allowing a measurement of output power of the power amplifier 943 that does not include insertion loss of the duplexing and switching circuit 945. The sensed output signal from the directional coupler 944 is provided to the observation receiver 961, which can include mixers for providing down conversion to generate downconverted I and Q signals, and DACs for generating I and Q observation signals from the downconverted I and Q signals.

The intermodulation detection circuit 962 determines an intermodulation product between the I and Q observation signals and the I and Q signals from the baseband processor 947. Additionally, the intermodulation detection circuit 962 controls the DPD provided by the DPD circuit 949 and/or a delay of the signal delay circuit 948 to control relative alignment between the differential analog envelope signal ENV_p, ENV_n and the RF signal RF_{IN}.

The delay of the envelope delay circuit 951 is selected based at least partly on an EVM detected at the output of the power amplifier 943. For example, in certain implementations, the delay is controlled based on an initial coarse calibration of the time delay based on EVM detected at the power amplifier's output, followed by a fine calibration of the time delay based on ACLR detected at the power amplifier's output.

Providing a feedback path from the output of the power amplifier 943 and baseband, the I and Q signals can be dynamically adjusted to optimize the operation of the communication system 970. For example, configuring the communication system 970 in this manner can aid in providing power control, compensating for transmitter impairments, and/or in performing DPD.

Although illustrated as a single stage, the power amplifier 943 can include one or more stages. Furthermore, the teachings herein are applicable to communication systems including multiple power amplifiers.

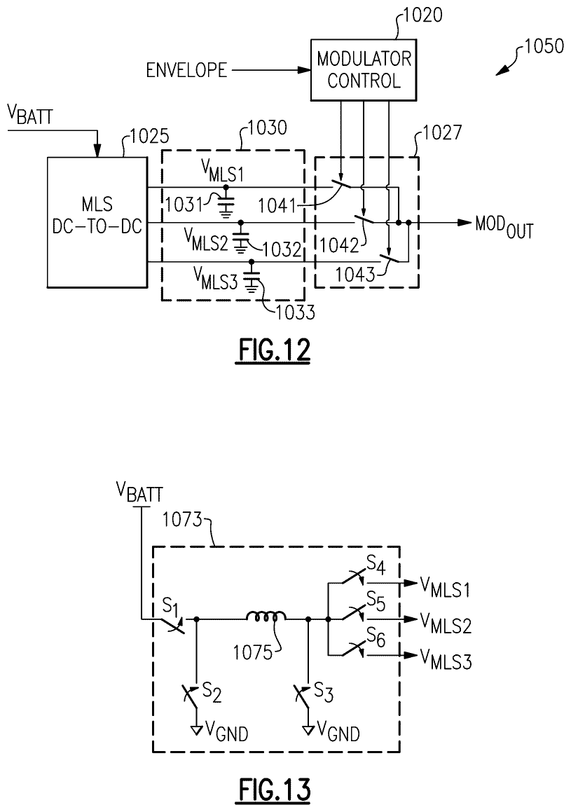

FIG. 12 is a schematic diagram of an MLS modulation system 1050 according to one embodiment. The MLS modulation system 1050 includes a modulator control circuit 1020, an MLS DC-to-DC converter 1025, a modulator switch bank 1027, and a decoupling capacitor bank 1030.

The MLS modulation system 1050 of FIG. 12 depicts another example of an envelope tracking system that can be calibrated in accordance with any of the delay calibration schemes disclosed herein.

The MLS DC-to-DC converter 1025 generates a first regulated voltage V_{MLS1}, a second regulated voltage V_{MLS2}, and a third regulated voltage V_{MLS3} based on providing DC-to-DC conversion of a battery voltage V_{BATT}. Although an example with three regulated voltages is shown, the MLS DC-to-DC converter 1025 can generate more or fewer regulated voltages. In certain implementations, at least a portion of the regulated voltages are boosted in voltage level relative to the battery voltage V_{BATT}. Additionally or alternatively, one or more of the regulated voltages is a buck voltage having a voltage level lower than that of the battery voltage V_{BATT}.

The decoupling capacitor bank 1030 aids in stabilizing the regulated voltages generated by the MLS DC-to-DC converter 1025. For example, the decoupling capacitor bank 1030 of FIG. 12 includes a first decoupling capacitor 1031 for decoupling the first regulated voltage V_{MLS1}, a second decoupling capacitor 1032 for decoupling the second regulated voltage V_{MLS2}, and a third decoupling capacitor 1033 for decoupling the third regulated voltage V_{MLS3}.

With continuing reference to FIG. 12, the modulator switch bank 1027 includes a first switch 1041 connected between the modulator's output (MOD_{OUT}) and the first regulated voltage V_{MLS1}, a second switch 1042 connected between the modulator's output and the second regulated voltage V_{MLS2}, and a third switch 1043 connected between the modulator's output and the third regulated voltage V_{MLS3}. The modulator control 1020 operates to selectively open or close the switches 1041-1043 to thereby control modulator's output based on an envelope signal ENVELOPE.

FIG. 13 is a schematic diagram of an MLS DC-to-DC converter 1073 according to one embodiment. The MLS DC-to-DC converter 1073 includes an inductor 1075, a first switch S₁, a second switch S₂, a third switch S₃, a fourth switch S₄, a fifth switch S₅, and a sixth switch S₆. The MLS DC-to-DC converter 1073 further includes control circuitry (not shown in FIG. 13) for opening and closing the switches to provide regulation.

The MLS DC-to-DC converter 1073 of FIG. 13 illustrates one implementation of an MLS DC-to-DC converter suitable for incorporation in a multi-level envelope tracker. However, other implementations of MLS DC-to-DC converters can be included in multi-level envelope trackers implemented in accordance with the teachings herein.

In the illustrated embodiment, the first switch S₁ includes a first end electrically connected to the battery voltage V_{BATT} and a second end electrically connected to a first end of the second switch S₂ and to a first end of the inductor 1075. The second switch S₂ further includes a second end electrically connected to a ground supply V_{GND} (also referred to herein as a ground voltage or ground). Although FIG. 13 illustrates a configuration of a DC-to-DC converter that is powered using a ground supply and a battery voltage, the teachings herein are applicable to DC-to-DC converters powered using any suitable power supplies. The inductor 1075 further includes a second end electrically connected to a first end of each of the third to sixth switches S₃-S₆. The third switch S₃ further includes a second end electrically connected to the ground supply V_{GND}. The fourth, fifth, and sixth switches S₄-S₆ each include a second end configured to generate the first, second, and third regulated voltages V_{MLS1}, V_{MLS2}, and V_{MLS3}, respectively.

The first to sixth switches S₁-S₆ are selectively opened or closed to maintain regulated voltages within a particular error tolerance of target voltage levels. Although an example with three regulated voltages is shown, the MLS DC-to-DC converter 1073 can be implemented to generate more or fewer regulated voltages.

In the illustrated embodiment, the MLS DC-to-DC converter 1073 operates as a buck-boost converter operable to generate regulated boost voltages greater than the battery voltage V_{BATT} and/or regulated buck voltages lower than the battery voltage V_{BATT}. However, other implementations are possible.

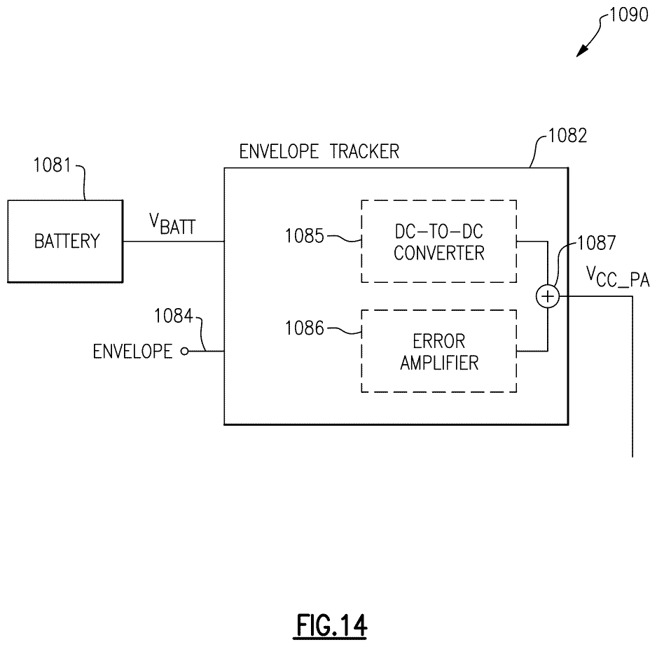

FIG. 14 is a schematic diagram of an envelope tracking system 1090 according to another embodiment. The envelope tracking system 1090 includes an envelope tracker 1082 and a battery 1081. The envelope tracking system 1090 of FIG. 14 depicts another example of an envelope tracking system that can be calibrated in accordance with any of the delay calibration schemes disclosed herein.

The envelope tracker 1082 receives a battery voltage V_{BATT} from the battery 1082 and an envelope signal 1084 corresponding to an envelope of an RF signal amplified by a power amplifier. Additionally, the envelope tracker 1082 generates a power amplifier supply voltage V_{CC_PA}, which supplies power to the power amplifier that amplifies the RF signal.

As shown in FIG. 14, the envelope tracker 1082 includes a DC-to-DC converter 1085 and an error amplifier 1086 that operate in combination with one another to generate the power amplifier supply voltage V_{CC_PA} based on the envelope signal 1084. Additionally, an output of the DC-to-DC converter 1085 and an output of the error amplifier 1086 are combined using a combiner 1087.

In the illustrated embodiment, the DC-to-DC converter 1085 and the error amplifier 1086 operate in parallel with one another to control the voltage level of the power amplifier supply voltage V_{CC_PA}. The combination of the DC-to-DC converter 1085 and the error amplifier 1086 provides effective tracking of the envelope signal 1084, since the DC-to-DC converter 1085 provides superior tracking of low frequency components of the envelope signal 1084 while the error amplifier 1086 provides superior tracking of high frequency components of the envelope signal 1084.

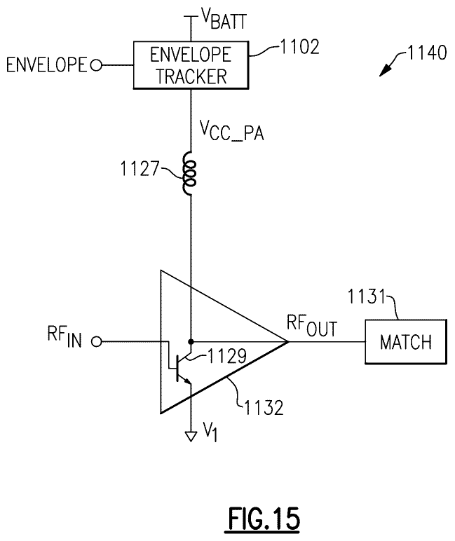

FIG. 15 is a schematic diagram of an envelope tracking system 1140 according to another embodiment. The envelope tracking system 1140 includes an envelope tracker 1102, an inductor 1127, an output impedance matching circuit 1131, and a power amplifier 1132. The illustrated envelope tracker 1102 receives a battery voltage V_{BATT} and an envelope of the RF signal and generates a power amplifier supply voltage V_{CC_PA} for the power amplifier 1132.

The envelope tracking system 1140 of FIG. 14 depicts another example of an envelope tracking system that can be calibrated in accordance with any of the delay calibration schemes disclosed herein.

The illustrated power amplifier 1132 includes a bipolar transistor 1129 having an emitter, a base, and a collector. As shown in FIG. 15, the emitter of the bipolar transistor 1129 is electrically connected to a power low supply voltage V₁, which can be, for example, a ground supply. Additionally, an RF signal (RF_{IN}) is provided to the base of the bipolar transistor 1129, and the bipolar transistor 1129 amplifies the RF signal to generate an amplified RF signal at the collector. The bipolar transistor 1129 can be any suitable device. In one implementation, the bipolar transistor 1129 is a heterojunction bipolar transistor (HBT).

The output impedance matching circuit 1131 serves to terminate the output of the power amplifier 1132, which can aid in increasing power transfer and/or reducing reflections of the amplified RF signal generated by the power amplifier 1132. In certain implementations, the output impedance matching circuit 1131 further operates to provide harmonic termination and/or to control a load line impedance of the power amplifier 1132.

The inductor 1127 can be included to provide the power amplifier 1132 with the power amplifier supply voltage V_{CC_PA} generated by the envelope tracker 1102 while choking or blocking high frequency RF signal components. The inductor 1127 can include a first end electrically connected to the envelope tracker 1102, and a second end electrically connected to the collector of the bipolar transistor 1129. In certain implementations, the inductor 1127 operates in combination with the impedance matching circuit 1131 to provide output matching.

Although FIG. 15 illustrates one implementation of the power amplifier 1132, skilled artisans will appreciate that the teachings described herein can be applied to a variety of power amplifier structures, such as multi-stage power amplifiers and power amplifiers employing other transistor structures. For example, in some implementations the bipolar transistor 1129 can be omitted in favor of employing a field-effect transistor (FET), such as a silicon FET, a gallium arsenide (GaAs) high electron mobility transistor (HEMT), or a laterally diffused metal oxide semiconductor (LDMOS) transistor. Additionally, the power amplifier 1132 can be adapted to include additional circuitry, such as biasing circuitry.

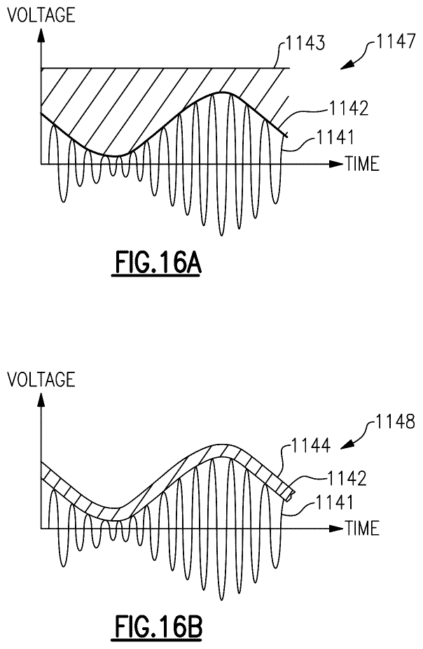

FIGS. 16A and 16B show two examples of power amplifier supply voltage versus time.

In FIG. 16A, a graph 1147 illustrates one example of the voltage of an RF signal 1141 and a power amplifier supply voltage 1143 versus time. The RF signal 1141 has an envelope 1142.

It can be important that the power amplifier supply voltage 1143 of a power amplifier has a voltage greater than that of the RF signal 1141. For example, powering a power amplifier using a power amplifier supply voltage that has a magnitude less than that of the RF signal can clip the RF signal, thereby creating signal distortion and/or other problems. Thus, it can be important the power amplifier supply voltage 1143 be greater than that of the envelope 1142. However, it can be desirable to reduce a difference in voltage between the power amplifier supply voltage 1143 and the envelope 1142 of the RF signal 1141, as the area between the power amplifier supply voltage 1143 and the envelope 1142 can represent lost energy, which can reduce battery life and increase heat generated in a wireless device.

In FIG. 16B, a graph 1148 illustrates another example of the voltage of an RF signal 1141 and a power amplifier supply voltage 1144 versus time. In contrast to the power amplifier supply voltage 1143 of FIG. 16A, the power amplifier supply voltage 1144 of FIG. 16B changes in relation to the envelope 1142 of the RF signal 1141. The area between the power amplifier supply voltage 1144 and the envelope 1142 in FIG. 16B is less than the area between the power amplifier supply voltage 1143 and the envelope 1142 in FIG. 16A, and thus the graph 1148 of FIG. 16B can be associated with a power amplifier system having greater energy efficiency.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A load modulated power amplifier system comprising:
a power amplifier configured to receive a radio frequency signal at an input and to provide an amplified radio frequency signal at an output;
a controllable load impedance coupled to the output of the power amplifier and having an impedance modulated by an envelope control signal; and
a calibration circuit configured to select a time delay for aligning the envelope control signal to the radio frequency signal, the time delay selected based at least partly on an error vector magnitude detected at the output of the power amplifier.

2. The load modulated power amplifier system of claim 1 wherein the calibration circuit is configured to perform a coarse calibration based on the error vector magnitude detected at the output of the power amplifier followed by a fine calibration based on an adjacent channel leakage ratio detected at the output of the power amplifier.

3. The load modulated power amplifier system of claim 1 further comprising a power management circuit configured to control a voltage level of a power amplifier supply voltage of the power amplifier.

4. The load modulated power amplifier system of claim 1 further comprising a digital-to-analog converter configured to generate an analog transmit signal based on a digital transmit signal and a signal modulator configured to generate the radio frequency signal based on the digital transmit signal.

5. The load modulated power amplifier system of claim 4 wherein the time delay controls a relative delay between the digital transmit signal and a digital representation of the envelope control signal.

6. The load modulated power amplifier system of claim 1 further comprising a directional coupler coupled to the output of the power amplifier and configured to generate a sensed signal, and an observation receiver configured to generate an observation signal for the calibration circuit based on the sensed signal.

7. The load modulated power amplifier system of claim 6 further comprising a baseband processor that includes the calibration circuit, the baseband processor configured to perform computations of the error vector magnitude based on the observation signal.

8. The load modulated power amplifier system of claim 1 wherein the calibration circuit is configured to periodically calibrate the time delay during operation of the power amplifier.

9. The load modulated power amplifier system of claim 1 wherein the calibration circuit is configured to calibrate the time delay to account for a change in one or more of a temperature of the power amplifier, a voltage standing wave ratio, or a frequency of the radio frequency signal.

10. The load modulated power amplifier system of claim 1 wherein the envelope control signal changes in relation to an envelope of the radio frequency signal.

11. A mobile device comprising:
a front end system including a power amplifier configured to receive a radio frequency signal at an input and to provide an amplified radio frequency signal at an output, and a controllable load impedance coupled to the output of the power amplifier and having an impedance that is modulated by an envelope control signal; and
a baseband processor including a calibration circuit configured to select a time delay for aligning the envelope control signal to the radio frequency signal, the time delay selected based at least partly on an error vector magnitude detected at the output of the power amplifier.

12. The mobile device of claim 11 wherein the calibration circuit is configured to perform a coarse calibration based on the error vector magnitude detected at the output of the power amplifier followed by a fine calibration based on an adjacent channel leakage ratio detected at the output of the power amplifier.

13. The mobile device of claim 11 further comprising a power management circuit configured to control a voltage level of a power amplifier supply voltage of the power amplifier.

14. The mobile device of claim 11 further comprising a transceiver including a digital-to-analog converter configured to generate an analog transmit signal based on a digital transmit signal and a signal modulator configured to generate the radio frequency signal based on the digital transmit signal.

15. The mobile device of claim 14 wherein the time delay controls a relative delay between the digital transmit signal and a digital representation of the envelope control signal.

16. The mobile device of claim 11 wherein the front-end system further includes a directional coupler coupled to the output of the power amplifier and configured to generate a sensed signal, the mobile device further comprising an observation receiver configured to generate an observation signal for the calibration circuit based on the sensed signal, the baseband processor is configured to perform computations of the error vector magnitude based on the observation signal.

17. The mobile device of claim 11 wherein the calibration circuit is configured to periodically calibrate the time delay during operation of the power amplifier.

18. The mobile device of claim 11 wherein the calibration circuit is configured to calibrate the time delay to account for a change in one or more of a temperature of the power amplifier, a voltage standing wave ratio, or a frequency of the radio frequency signal.

19. The mobile device of claim 11 wherein the envelope control signal changes in relation to an envelope of the radio frequency signal.

20. A method of power amplification in a mobile device, the method comprising:
receiving a radio frequency signal at an input to a power amplifier and providing an amplified radio frequency signal at an output of the power amplifier;
modulating an impedance of a controllable load impedance coupled to the output of the power amplifier using an envelope control signal; and
selecting a time delay for aligning the envelope control signal to the radio frequency signal using a calibration circuit, the time delay selected based at least partly on an error vector magnitude detected at the output of the power amplifier.

21-83. (canceled)
